(19) United States
(12) Patent Application Publication
(10) Pub. No.: US 2012/0181615 A1
(43) Pub. Date: Jul. 19, 2012

(54) METHOD OF MANUFACTURING SEMICONDUCTOR DEVICE AND SEMICONDUCTOR DEVICE

(75) Inventors: Tatsuo SHIMIZU, Kanagawa (JP); Shinji YOKOGAWA, Kanagawa (JP); Satoshi UNO, Kanagawa (JP); Hideaki TSUCHIYA, Kanagawa (JP)

(73) Assignee: Renesas Electronics Corporation, Kanagawa (JP)

(21) Appl. No.: 13/346,579

(22) Filed: Jan. 9, 2012

(30) Foreign Application Priority Data
Jan. 17, 2011 (JP) 2011-006699

(51) Int. Cl. H01L 27/088; H01L 21/66

(52) U.S. Cl. 257/368; 438/17; 257/E21.531; 257/E27.06

(57) ABSTRACT

A distance between a contact and a gate electrode can be measured efficiently. Conversion data indicating a correlation between the distance between the first gate electrode and the first contact and a magnitude of a leakage current amount is prepared in advance. The leakage current amount between the first gate electrode and the first contact is measured, and the measured leakage current amount is converted into the distance between the first gate electrode and the first contact by using the conversion data. Then, a superposition error between an exposure process for forming the first gate electrode and an exposure process for forming the first contact can be measured from a difference between the measured value of the distance between the first gate electrode and the first contact and a design value of the distance.

### CROSS-REFERENCES TO RELATED APPLICATIONS

The disclosure of Japanese Patent Application No. 2011-6699 filed on Jan. 17, 2011 including the specification, drawings and abstract is incorporated herein by reference in its entirety.

### BACKGROUND

The present invention relates to a method of manufacturing a semiconductor device and a semiconductor device.

In a semiconductor device, an insulation performance required for an insulating film may disappear due to time degradation of the insulating film. The characteristics of a semiconductor device regarding such degradation of insulation performance are called TDDB (Time Dependent Dielectric Breakdown) characteristics.

On the other hand, Japanese Unexamined Patent Application Publication No. 2009-10135 discloses TEG for measuring an influence of the distance between a contact of source/drain of a transistor and the gate electrode of the transistor, which affects DC characteristics of the transistor.

In recent years, miniaturization of semiconductor devices advances, and the distance between a contact of source/drain of a transistor and the gate electrode of the transistor becomes small. Therefore, it becomes necessary to evaluate the TDDB characteristics of an insulating film located between the contact and the gate electrode. The TDDB characteristics are largely affected by the distance between the contact and the gate electrode. However, the distance between the contact and the gate electrode could not be measured efficiently so far.

According to one aspect of the present invention, there is provided a method of manufacturing a semiconductor device, which includes the steps of preparing a semiconductor device including a first contact and a first gate electrode located adjacent to the first contact, measuring a first leakage current generated between the first contact and the first gate electrode, obtaining conversion data indicating a correlation between a distance between a contact coupled to an impurity layer that is a source or a drain of a transistor and a gate electrode of the transistor and a magnitude of a leakage current generated between the contact and the gate electrode, and calculating a distance between the first contact and the first gate electrode by using the first leakage current and the conversion data.

The inventors found that a magnitude of leakage current generated between the contact and the gate electrode has a correlation with the distance between the contact and the gate electrode, so that the inventors invented the above-described invention. In the present invention, a measurement result of the first leakage current is converted into the distance between the first contact and the first gate electrode by using the conversion data. Therefore, the measurement efficiency can be higher than that in a case in which the actual distance between the first contact and the first gate electrode is measured.

According to another aspect of the present invention, there is provided a method of manufacturing a semiconductor device, which includes the steps of preparing a semiconductor device including a TEG having a first contact, a first gate electrode located adjacent to the first contact, and a transistor, measuring a first leakage current generated between the first contact and the first gate electrode, obtaining conversion data indicating a correlation between a TDDB life between a contact coupled to an impurity layer that is a source or a drain of a transistor and a gate electrode of the transistor and a magnitude of a leakage current generated between the contact and the gate electrode, and calculating the TDDB life between the contact and the gate electrode of the transistor by using the first leakage current and the conversion data.

According to still another aspect of the present invention, there is provided a semiconductor device, which includes a substrate, an insulating film formed over a surface of the substrate, and a TEG formed over the insulating film, and in which the TEG includes first gate electrode located over the insulating film, a first contact which is located over the insulating film and located adjacent to the first gate electrode, a first electrode pad coupled to the first contact, and a second electrode pad coupled to the first gate electrode.

According to the aspects of the present invention, the distance between the contact and the gate electrode can be measured efficiently.

### BRIEF DESCRIPTION OF THE DRAWINGS

FIG. 1 is a cross-sectional view showing a configuration of a semiconductor device according to a first embodiment;

FIG. 2 is a plan view of the semiconductor device shown in FIG. 1;

FIG. 3 is a plan view showing a modified example of FIG. 2;

FIG. 4 is a diagram showing an example of a relationship between a distance between a first gate electrode and a first contact and a magnitude of leakage current generated between the first gate electrode and the first contact;

FIG. 5 is a graph showing a relationship between electric field intensity generated between a gate electrode and a contact and a TDDB life between the gate electrode and the contact;

FIG. 6 is a flowchart showing a first example of a method of manufacturing a semiconductor device;

FIG. 7 is a plan view for explaining a state in which semiconductor devices are diced;

FIG. 8 is a flowchart for explaining a second example of the method of manufacturing the semiconductor device shown in FIGS. 1 and 2;

FIG. 9 is a plan view showing a configuration of TEG used in a semiconductor device according to a second embodiment;

FIG. 10 is a plan view showing a configuration of TEG used in a semiconductor device according to a third embodiment;

FIG. 11 is a plan view showing a configuration of TEG used in a semiconductor device according to a fourth embodiment;

FIG. 12 is a plan view showing a configuration of TEG used in a semiconductor device according to a fifth embodiment;

FIG. 13 is a plan view showing a configuration of TEG used in a semiconductor device according to a sixth embodiment;

FIG. 14 is a plan view showing a configuration of TEG used in a semiconductor device according to a seventh embodiment;

FIG. 15 is a plan view showing a configuration of TEG used in a semiconductor device according to an eighth embodiment;

FIG. 16 is a plan view showing a configuration of TEG used in a semiconductor device according to a ninth embodiment; and

FIG. 17 is a plan view showing a configuration of TEG used in a semiconductor device according to a tenth embodiment.

### DETAILED DESCRIPTION

Hereinafter, embodiments of the present invention will be described. In all the drawings, the same constituent elements are given the same reference numerals and the description thereof will be appropriately omitted.

### First Embodiment

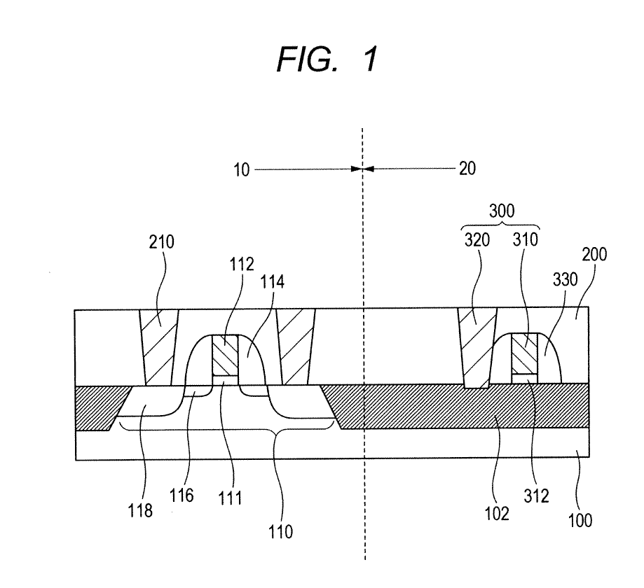

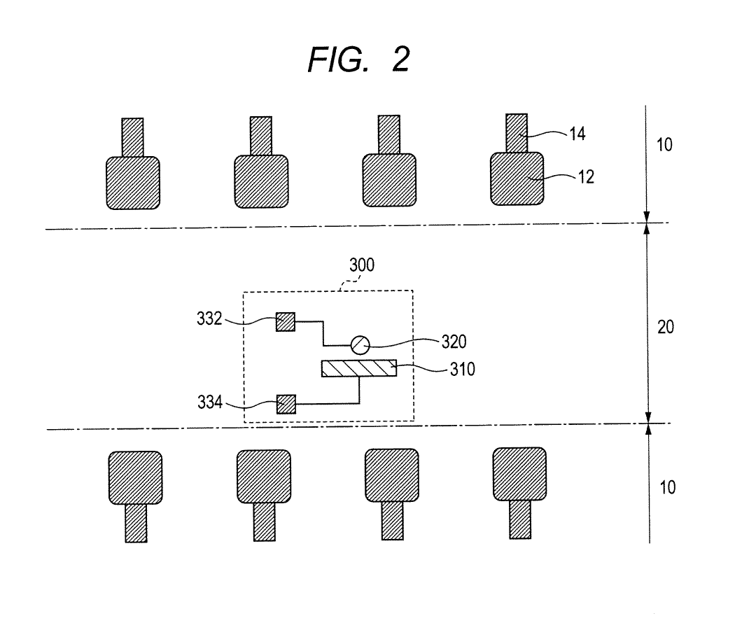

FIG. 1 is a cross-sectional view showing a configuration of a semiconductor device according to a first embodiment. FIG. 2 is a plan view of the semiconductor device shown in FIG. 1. FIG. 1 shows a vertical cross-section of FIG. 2. The semiconductor device has a substrate 100, an element separating film (insulating film) 102, a first gate electrode 310, a first contact 320, a first electrode pad 332 (not shown in FIG. 1), and a second electrode pad 334 (not shown in FIG. 1). The element separating film 102 is partially formed on a surface of the substrate 100. The first gate electrode 310 is located on the element separating film 102. The first contact 320 is located on the element separating film 102 and located adjacent to the first gate electrode 310. The first electrode pad 332 is coupled to only the first contact 320 via a line, a via, and a contact, and the second electrode pad 334 is coupled to only the first gate electrode 310 via a line, a via, and a contact.

In the present embodiment, the first gate electrode 310 and the first contact 320 form a TEG 300. The TEG 300 is a TEG for measuring a positional shift between the first gate electrode 310 and the first contact 320 (mask superposition error).

Specifically, conversion data indicating a correlation between the distance between the first gate electrode 310 and the first contact 320 and a magnitude of a leakage current amount is prepared in advance. The leakage current amount between the first gate electrode 310 and the first contact 320 is measured, and the measured leakage current amount is converted into the distance between the first gate electrode 310 and the first contact 320 by using the conversion data. Then, a superposition error between an exposure process for forming the first gate electrode 310 and an exposure process for forming the first contact 320 can be measured from a difference between the measured value of the distance between the first gate electrode 310 and the first contact 320 and a design value of the distance. Hereinafter, the details will be described.

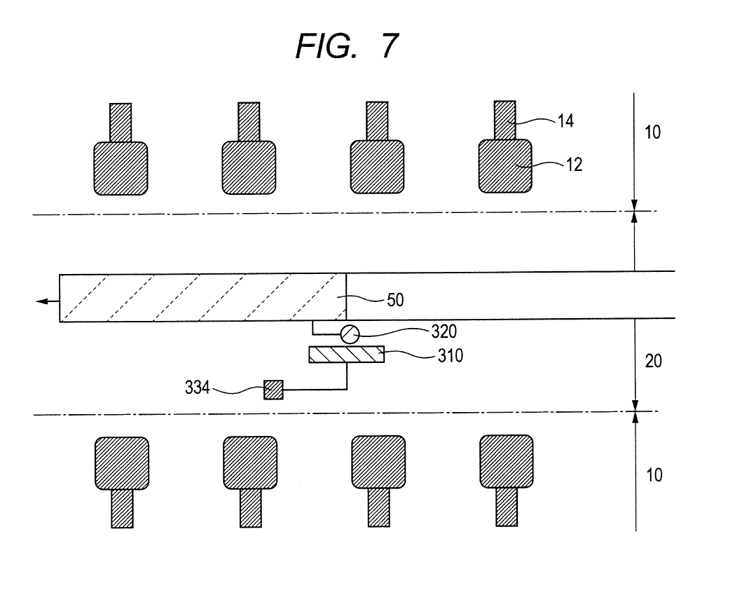

First, the configuration of the semiconductor device will be described. In the semiconductor device, the TEG 300 is disposed in a scribe area 20. The scribe area 20 is located between multiple chip areas 10, which will be semiconductor chips. A dicing blade 50 (see FIG. 7) passes through the scribe area 20 when the semiconductor chips are separated into individual chips.

In the present embodiment, the TEG 300 is located on the element separating film 102. Thereby, a current flowing between the first gate electrode 310 and the first contact 320 can be assumed to be a leakage current generated between the first gate electrode 310 and the first contact 320. However, the TEG 300 may not have to be located on an insulating film such as the element separating film 102 depending on a correction method. The first contact 320 is buried in an interlayer insulating film 200 formed on the substrate 100.

A gate insulating film 312 is formed between the first gate electrode 310 of the TEG 300 and the element separating film 102. A side wall 330 is formed on a side surface of the first gate electrode 310.

In the chip area 10, a transistor 110 (not shown in FIG. 2) including a circuit, a line 14 coupled to the transistor 110, and an electrode pad 12 (not shown in FIG. 1) are located. The transistor 110 has a gate insulating film 111, a gate electrode 112, a side wall 114, an extension area 116, and an impurity layer 118. The gate insulating film 111 is made of a film (High-K film) formed of a material having a dielectric constant higher than that of silicon oxide, and for example, formed by a deposition method. The impurity layer 118 is coupled to a second contact 210. The second contact 210 is buried in the interlayer insulating film 200.

As shown in FIG. 2, the first gate electrode 310 is disposed extending in parallel with an extending direction of the scribe area 20. The first contact 320 is separated from the first gate electrode 310 in a direction perpendicular to the extending direction of the scribe area 20. When such a TEG 300 is used, a superposition error in a direction perpendicular to the extending direction of the scribe area 20 can be measured.

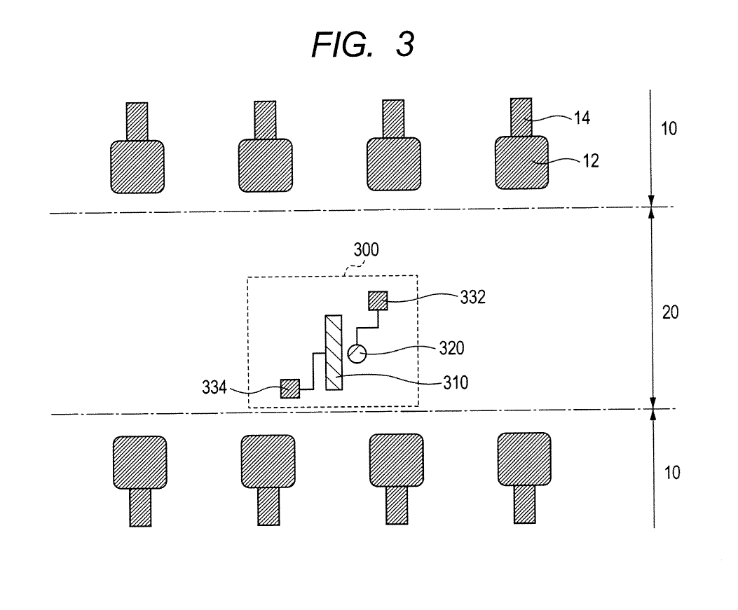

However, as shown in FIG. 3, the first gate electrode 310 may be disposed extending in a direction perpendicular to the extending direction of the scribe area 20. In this case, the first contact 320 is separated from the first gate electrode 310 in the extending direction of the scribe area 20. When such a TEG 300 is used, a superposition error in a direction parallel with the extending direction of the scribe area 20 can be measured.

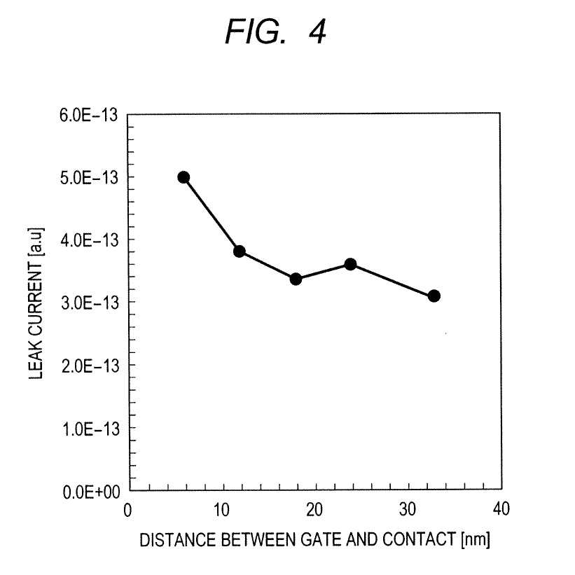

FIG. 4 shows an example of a relationship between the distance between the first gate electrode 310 and the first contact 320 and a magnitude of leakage current generated between the first gate electrode 310 and the first contact 320. As seen from FIG. 4, when a voltage is applied between the first gate electrode 310 and the first contact 320, a small amount of leakage current is generated between the first gate electrode 310 and the first contact 320. When the structures of the first electrode 310, the first contact 320, and the insulating film located between the first electrode 310 and the first contact 320 are the same and the voltage applied between the first electrode 310 and the first contact 320 is constant, the leakage current amount generated between the first electrode 310 and the first contact 320 decreases as the distance between the first electrode 310 and the first contact 320 increases. Therefore, the data shown in FIG. 4 is measured in advance and the measured result is held as the conversion data, so that the distance between the first gate electrode 310 and the first contact 320 can be measured from a measured value of the amount of current flowing between the first gate electrode 310 and the first contact 320.

The relationship between the distance between the first gate electrode 310 and the first contact 320 and the magnitude of leakage current generated between the first gate electrode 310 and the first contact 320 varies depending on the configuration of the semiconductor device, such as material of the first gate electrode 310, material of the first contact 320, shape of the first gate electrode 310, shape of the first contact 320, structure of the side wall 330, and material of the interlayer insulating film 200. Therefore, actually, the conversion data shown in FIG. 4 is calculated by an actual measurement for each semiconductor device and stored in an inspection apparatus, and the inspection apparatus may read conversion data corresponding to a semiconductor device to be inspected when the inspection is performed.

The formula (1) described below which represents Schottky emission or Poole-Frenkel current can be applied to the magnitude of the leakage current generated between the first gate electrode 310 and the first contact 320.

$$J ∝ {J}_{0} exp ( \frac{β \sqrt{V}}{kT \sqrt{s}} ) \qquad ( 1 )$$

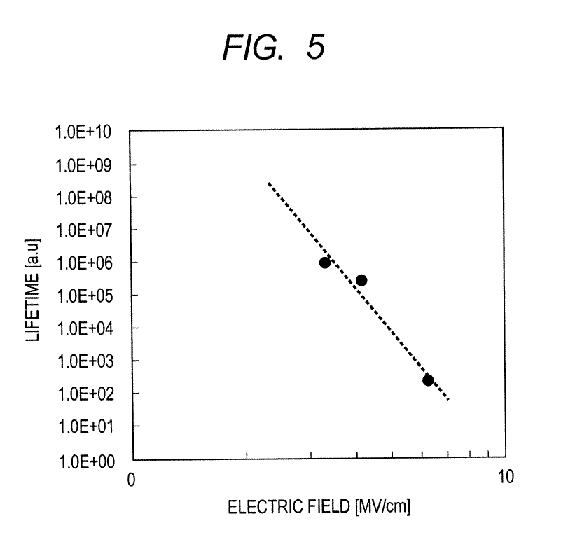

FIG. 5 is a graph showing a relationship between electric field intensity generated between a gate electrode of a transistor and a contact coupled to the source/drain of the transistor and a TDDB life between the gate electrode and the contact. As the electric field intensity between the gate electrode and the contact increases, the TDDB life between the gate electrode and the contact decreases accordingly. The electric field intensity between the gate electrode and the contact can be calculated by a difference between potentials applied to the gate electrode and the contact and a distance between the gate electrode and the contact. The difference between potentials is known when designing the semiconductor device. Therefore, when the distance between the gate electrode and the contact is calculated by the method described with reference to FIG. 4, an estimate of the TDDB life between the gate electrode and the contact can be calculated.

The phenomenon shown in FIG. 5 can be explained by the theory described below. In a failure due to dielectric breakdown caused by the TDDB between the contact and the gate electrode, a dielectric breakdown life t is subjected to the Weibull distribution represented by the following formula (2).

$$F ( t ) = 1 - exp ( - {( \frac{t}{η} )}^{β} ) \qquad ( 2 )$$

Here, β is a geometry parameter of the Weibull distribution and η is a scale parameter (characteristic life) of the Weibull distribution. When the distance between the contact and the gate electrode varies due to the superposition error and an applied electric field intensity E varies, cumulative failure probability varies through electric field acceleration of the scale parameter η=η(E). The cumulative failure probability in actual use is estimated by the formula (2). For the TDDB of a silicon oxide film and the TDDB of a low-k film, a power-law model represented by the formula (3) and a √E model represented by the formula (4) are proposed as an electric field acceleration model. ([Related Art Document 1] E. Wu, et al., IEEE Tran. Electron Devices, vol. 49, p. 2244 (2002), [Related Art Document 2] F. Chen, et al., IRPS 2006, p. 46)

$$\begin{matrix}η ( E ) ∝ {( E )}^{- n} = {( \frac{V}{s} )}^{- n} & ( 3 ) \\ η ( E ) ∝ exp ( - γ \sqrt{E} ) = exp ( - γ \sqrt{\frac{V}{s}} ) & ( 4 )\end{matrix}$$

Here, V is an applied voltage and s is the distance between the contact and the gate. Further, n is an exponent of an electric field acceleration term in the power law model and γ is an electric field acceleration coefficient in the √E model. If these models are applied, it is possible to estimate variation of a life distribution when the distance s varies due to the superposition error.

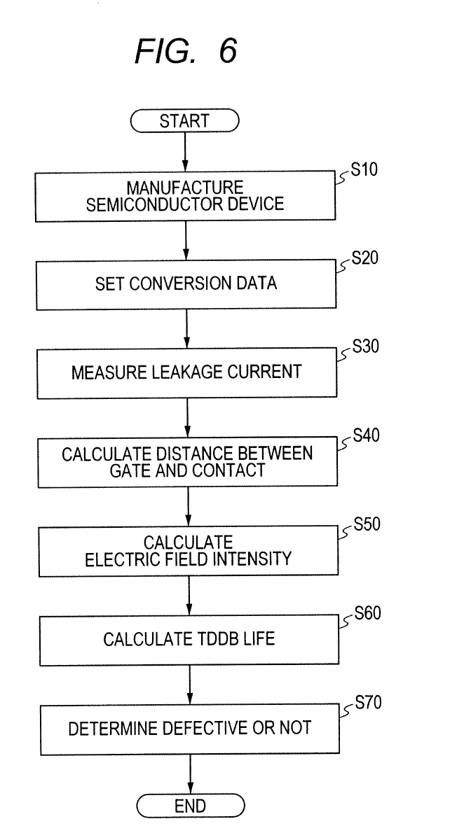

Next, a first example of a method of manufacturing the semiconductor device will be described with reference to a flowchart in FIG. 6. First, each constituent element of the semiconductor device is formed (step S10).

Specifically, first, the element separating film 102 is formed on the substrate 100. Next, the gate insulating film 111 and the gate insulating film 312 are formed, and further, the gate electrode 112 and the first gate electrode 310 are formed. At this time, the gate insulating film 111 and the gate insulating film 312 are formed in the same process, and the gate electrode 112 and the first gate electrode 310 are formed in the same process. In other words, the gate insulating film 111 and the gate insulating film 312 are formed to the same thickness by the same material, and the gate electrode 112 and the first gate electrode 310 are formed to the same thickness by the same material.

Next, impurities are injected into the substrate 100 by using the element separating film 102 as a mask. Thereby, the extension area 116 of the transistor 110 is formed. Next, the side wall 114 and the side wall 330 are formed. The side wall 114 and the side wall 330 are also formed in the same process. Next, impurities are injected into the substrate 100 by using the element separating film 102 and the side wall 114 as a mask. Thereby, the impurity layer 116 is formed.

In this way, the transistor 110 and the first gate electrode 310 of the TEG 300 are formed. Next, the interlayer insulating film 200 is formed on the transistor 110 and the first gate electrode 310, and the second contact 210 and the first contact 320 are buried into the interlayer insulating film 200. The second contact 210 and the first contact 320 are formed in the same process and have at least the same shape of upper ends.

Thereafter, a required number of wiring layers are formed on the interlayer insulating film 200, the second contact 210, and the first contact 320. At this time, the electrode pads 12, 332, and 334 are formed on the uppermost wiring layer. Next, a protective insulating layer is formed on the multiple wiring layers. The protective insulating layer has openings for exposing the electrode pads.

In this way, semiconductor devices before being separated into individual chips are formed. Next, inspection of the semiconductor device is performed (steps S20 to S60).

Specifically, first, the inspection apparatus reads the conversion data corresponding to the semiconductor device to be inspected and sets the conversion data (step S20). Next, the inspection apparatus causes probe needles to come into contact with the first electrode pad 332 and the second electrode pad 334, applies a predetermined voltage between the electrode pads, and measures a current (leakage current) flowing between the first electrode pad 332 and the second electrode pad 334 (step S30).

Next, the inspection apparatus calculates the distance between the first gate electrode 310 and the first contact 320 by using the conversion data read in step S20 and the leakage current measured in step S30. Next, the inspection apparatus calculates the superposition error between the first gate electrode 310 and the first contact 320 on the basis of the calculated distance. Next, the inspection apparatus calculates the distance between the gate electrode 112 and the second contact 210 by using the superposition error (step S40). If the design value of the distance between the first gate electrode 310 and the first contact 320 is the same as the design value of the distance between the gate electrode 112 and the second contact 210, the distance between the first gate electrode 310 and the first contact 320 can be assumes to be the distance between the gate electrode 112 and the second contact 210 without change.

Next, the inspection apparatus calculates the electric field intensity between the gate electrode 112 and the second contact 210 by using the distance between the gate electrode 112 and the second contact 210 and a design value of the voltage applied between the gate electrode 112 and the second contact 210 (step S50). Next, the inspection apparatus calculates the TDDB life of the semiconductor device by using the electric field intensity between the gate electrode 112 and the second contact 210 and the data shown in FIG. 5 (step S60). If the calculated TDDB life does not satisfy a criterion, the inspection apparatus determines that the semiconductor device is defective.

Thereafter, the semiconductor devices are diced into individual chips.

FIG. 7 is a plan view for explaining a state in which the semiconductor devices are diced. As shown in FIG. 7, the dicing blade passes through the scribe area 20, so that the chip areas 10 are separated from each other. At this time, at least a part of the TEG 300 remains in a semiconductor device separated into an individual chip.

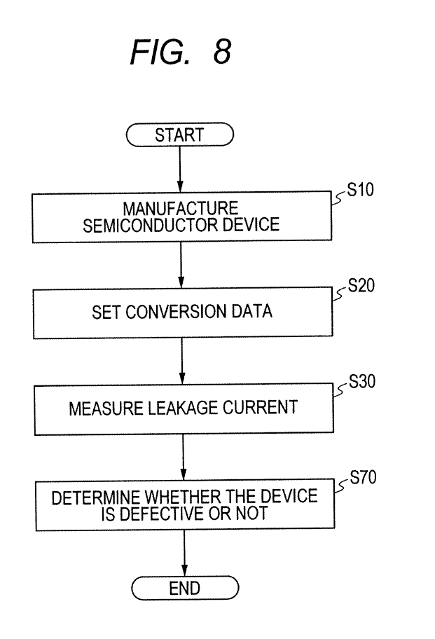

FIG. 8 is a flowchart for explaining a second example of the method of manufacturing the semiconductor device shown in FIGS. 1 and 2. In the example shown in FIG. 6, the leakage current amount measured in step S30 is converted into the distance between the gate electrode and the contact, and the distance is converted into the TDDB life. However, the leakage current amount measured in step S30 has a correlation with the TDDB life. Therefore, the TDDB life can be directly calculated from the leakage current amount. Further, it is possible to determine whether the semiconductor device is defective or not by defining a leakage current amount corresponding to a threshold value of the TDDB life as a threshold current amount in advance and determining whether or not the leakage current amount measured in step S30 exceeds the threshold current amount (step S70).

Next, the functions and effects of the present embodiment will be described. According to the present embodiment, the leakage current amount between the first gate electrode 310 and the first contact 320 is measured. The leakage current amount is converted into the distance between the first gate electrode 310 and the first contact 320 by using the conversion data. Therefore, the efficiency of the measurement of the distance between the first gate electrode 310 and the first contact 320 can be improved.

Thereby, the TDDB life between the gate electrode 112 and the second contact 210 of the semiconductor device can be efficiently calculated. Therefore, a defective semiconductor device can be efficiently detected.

### Second Embodiment

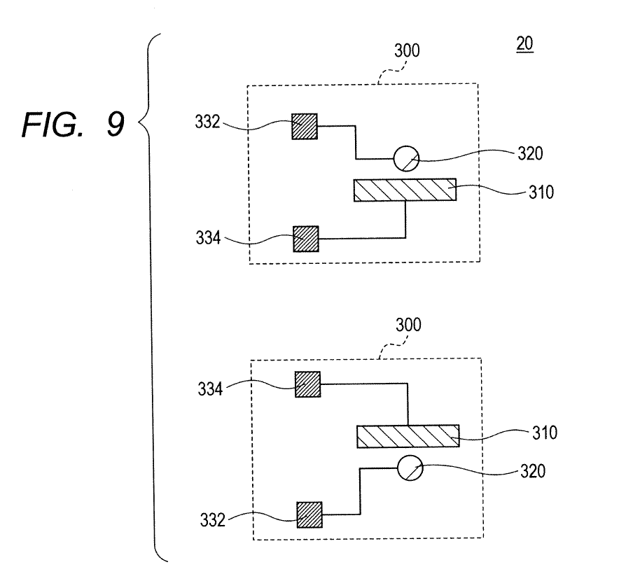

FIG. 9 is a plan view showing a configuration of TEG 300 used in a semiconductor device according to a second embodiment. The semiconductor device according to the present embodiment has at least two TEGs 300. In a first and a second TEGs 300, the first gate electrodes 310 extend in the same direction. However, the positions of the first contacts 320 with respect to the first gate electrodes 310 are opposite to each other.

In the semiconductor device according to the present embodiment, the process shown in FIG. 6 or FIG. 8 is performed by using the first TEG 300 and the process shown in FIG. 6 or FIG. 8 is performed by using the second TEG 300. Thereby, as seen from a direction perpendicular to the extending direction of the first gate electrode 310, even when a superposition error occurs between the first gate electrode 310 and the first contact 320 in either direction, it is possible to detect the magnitude of the superposition error and the decrease of the TDDB life.

### Third Embodiment

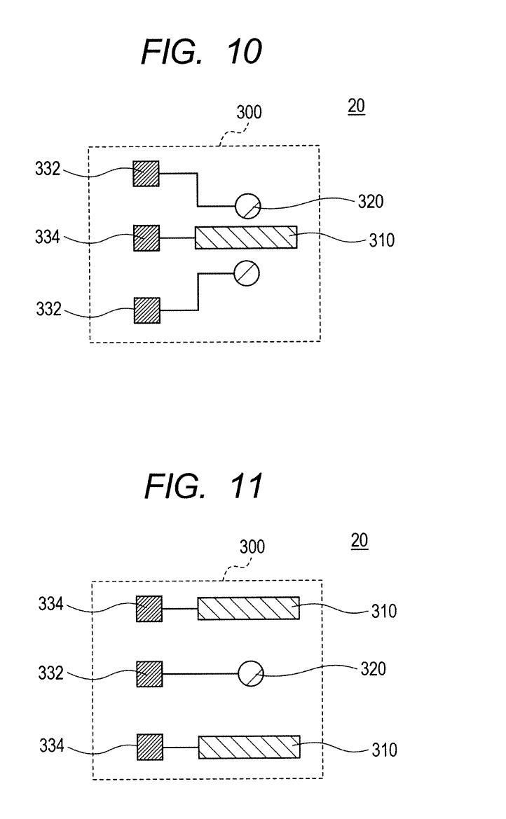

FIG. 10 is a plan view showing a configuration of TEG 300 used in a semiconductor device according to a third embodiment. The TEG 300 according to the present embodiment is the same as that of the first embodiment except that the TEG 300 has the first contact 320 at both sides of the first gate electrode 310. In other words, a second first contact 320 is located opposite to a first first contact 320 with respect to the first gate electrode 310. The first first contact 320 and the second first contact 320 are respectively coupled to different first electrode pads 332.

In the semiconductor device according to the present embodiment, the process shown in FIG. 6 or FIG. 8 is performed by using the first first contact 320 and the process shown in FIG. 6 or FIG. 8 is performed by using the second first contact 320. Thereby, as seen from a direction perpendicular to the extending direction of the first gate electrode 310, even when a superposition error occurs between the first gate electrode 310 and the first contact 320 in either direction, it is possible to detect the magnitude of the superposition error and the decrease of the TDDB life.

### Fourth Embodiment

FIG. 11 is a plan view showing a configuration of TEG 300 used in a semiconductor device according to a fourth embodiment. The TEG 300 according to the present embodiment is the same as that of the first embodiment except that the TEG 300 has two first gate electrodes 310 extending in parallel with each other at both sides of the first contact 320. The two first gate electrodes 310 are respectively coupled to different second electrode pads 334.

In the semiconductor device according to the present embodiment, the process shown in FIG. 6 or FIG. 8 is performed by using a first first gate electrode 310 and the process shown in FIG. 6 or FIG. 8 is performed by using a second first gate electrode 310. Thereby, as seen from a direction perpendicular to the extending direction of the first gate electrode 310, even when a superposition error occurs between the first gate electrode 310 and the first contact 320 in either direction, it is possible to detect the magnitude of the superposition error and the decrease of the TDDB life.

### Fifth Embodiment

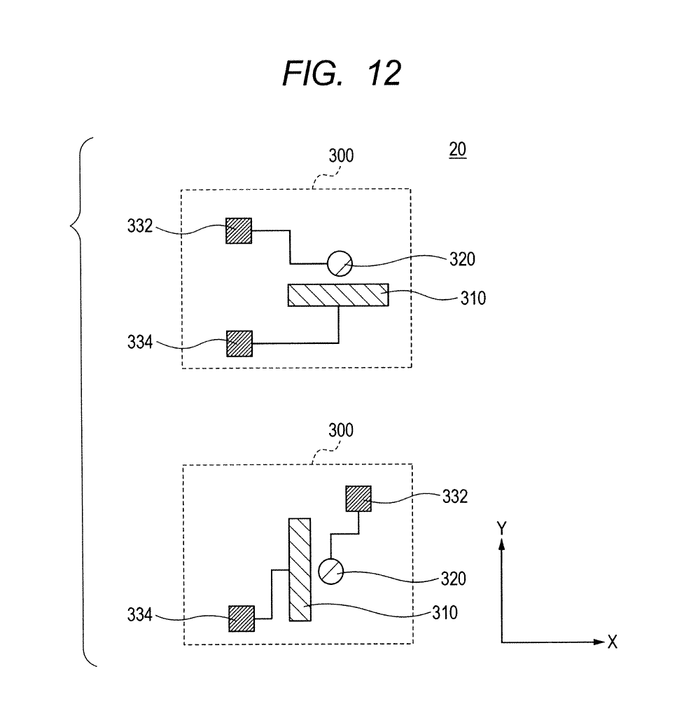

FIG. 12 is a plan view showing a configuration of TEG 300 used in a semiconductor device according to a fifth embodiment. The semiconductor device according to the present embodiment has two types of TEGs 300. In a first and a second TEGs 300, the first gate electrodes 310 respectively extend in directions different from each other. Specifically, the first gate electrode 310 of the second TEG 300 extends in a direction perpendicular to the extending direction of the first gate electrode 310 of the first TEG 300.

In the semiconductor device according to the present embodiment, the process shown in FIG. 6 or FIG. 8 is performed by using the first TEG 300 and the process shown in FIG. 6 or FIG. 8 is performed by using the second TEG 300. Thereby, even when a superposition error occurs between the first gate electrode 310 and the first contact 320 in the X direction and/or the Y direction in FIG. 12, it is possible to detect the magnitude of the superposition error and the decrease of the TDDB life.

### Sixth Embodiment

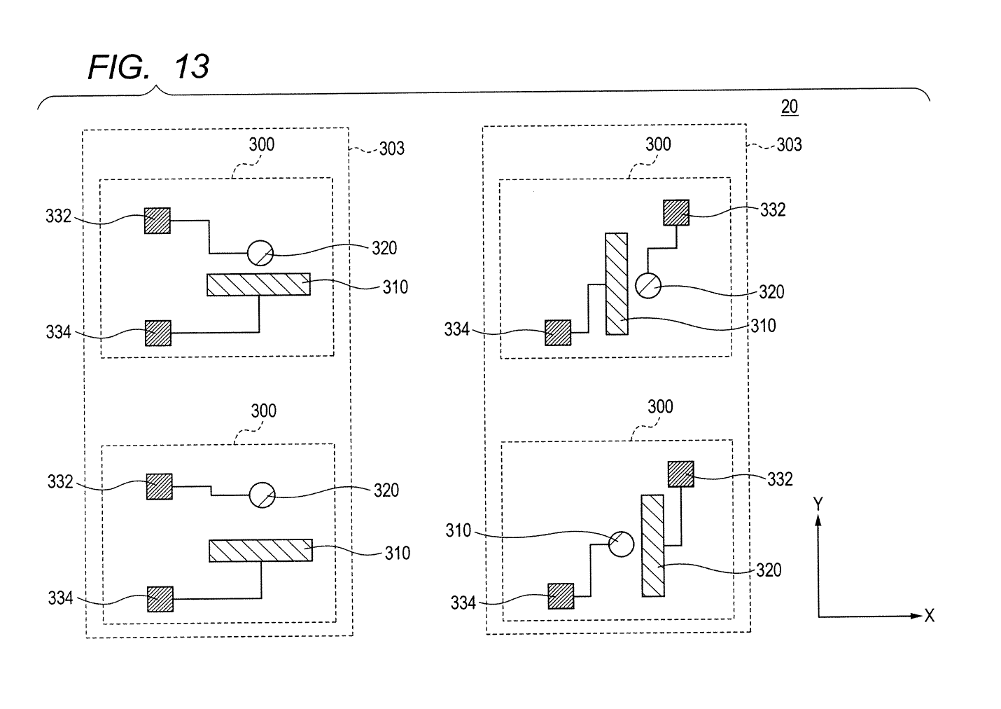

FIG. 13 is a plan view showing a configuration of TEG 300 used in a semiconductor device according to a sixth embodiment. The TEG 300 according to the present embodiment has two TEG groups 303 including two TEGs 300 shown in FIG. 9. The extending direction of the first gate electrodes 310 in one TEG group 303 is different from that in the other TEG group 303. Specifically, the first gate electrodes 310 of a second TEG group 303 extend in a direction perpendicular to the extending direction of the first gate electrodes 310 of a first TEG group 303.

In the present embodiment, the process shown in FIG. 6 or FIG. 8 is performed by using the TEGs 300. In the present embodiment, even when a superposition error occurs in the X direction and/or the Y direction in FIG. 13, it is possible to detect the magnitude of the superposition error and the decrease of the TDDB life. Further, even when a superposition error occurs in an X-positive direction and/or an X-negative direction in FIG. 13, it is possible to detect the magnitude of the superposition error and the decrease of the TDDB life. Furthermore, even when a superposition error occurs in a Y-positive direction and/or a Y-negative direction in FIG. 13, it is possible to detect the magnitude of the superposition error and the decrease of the TDDB life.

A superposition error (dx, dy) at a point where the TEG group 303 is provided can be calculated. It is possible to calculate an in-plane distribution of superposition errors (for example, distribution in the chip area 10) by applying the superposition error to a linear interpolation model formula representing positional dependence of the superposition error. An example of such a model formula is the formula (5) (W. H. Arnold, SPIE 1988) described below.

dX=−(θₛ+θ_{skew})Y+M_{X}X+∈_{X}

dY=θₛX+M_{Y}Y+∈_{Y} (5)

Here, θₛ is a coefficient of rotation direction error, M_{X} is a coefficient of magnification error in the horizontal direction, M_{Y} is a coefficient of magnification error in the vertical direction, and θ_{skew} is a coefficient of orthogonality error. The terms ∈_{X} and ∈_{Y} represent effects of residual nonlinear errors that cannot be represented by linear models in the horizontal and vertical directions.

In the present embodiment, the TEG 300 shown in FIG. 10 or FIG. 11 may be used instead of each TEG group 303. In this case, the same effects as those of the present embodiment can be obtained.

### Seventh Embodiment

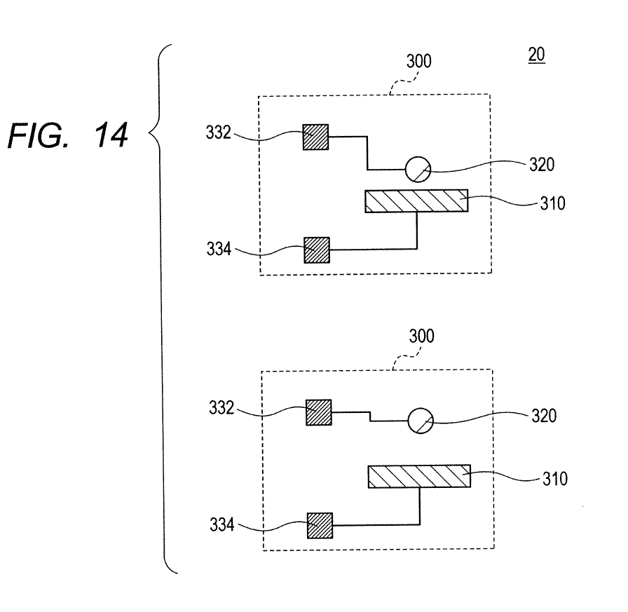

FIG. 14 is a plan view showing a configuration of TEG 300 used in a semiconductor device according to a seventh embodiment. The semiconductor device according to the present embodiment has multiple TEGs 300. The extending direction of the first gate electrode 310 in each TEG 300 is the same. However, the distance between the first gate electrode 310 and the first contact 320 is different from each other. In the present embodiment, the process shown in FIG. 6 or FIG. 8 is performed on each TEG 300.

Also in the present embodiment, the same effects as those of the present embodiment can be obtained. In the method described with reference to FIG. 4, the calculation accuracy varies depending on the distance between the first gate electrode 310 and the first contact 320. On the other hand, the present embodiment includes multiple TEGs 300 in each of which a distance between the first gate electrode 310 and the first contact 320 is different from that in the other TEGs 300. Therefore, it is possible to improve the calculation accuracy of the magnitude of the superposition error and the TDDB life by performing the process shown in FIG. 6 or FIG. 8 using the TEGs 300.

### Eighth Embodiment

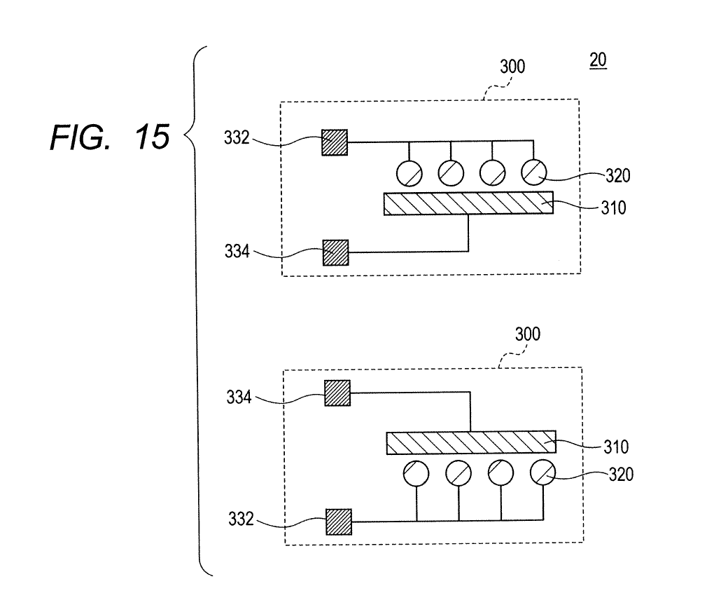

FIG. 15 is a plan view showing a configuration of TEG 300 used in a semiconductor device according to an eighth embodiment. The TEG 300 according to the present embodiment is the same as that of the second embodiment except that the TEG 300 has multiple first contacts 320 for one first gate electrode 310.

Specifically, multiple first contacts 320 included in one TEG 300 are located on the same side with respect to the first gate electrode 310, and the distances between the first contacts 320 and the first gate electrode 310 are the same. The first contacts 320 included in one TEG 300 are coupled to the same first electrode pad 332.

Also in the present embodiment, the same effects as those of the second embodiment can be obtained. The summation of leakage currents flowing between the first contacts 320 and the first gate electrode 310 flows between the first electrode pad 332 and the second electrode pad 334. Therefore, even when the leakage current amount per the first contact 320 is very small, it is possible to calculate the magnitude of the superposition error and the TDDB life at a high degree of accuracy.

### Ninth Embodiment

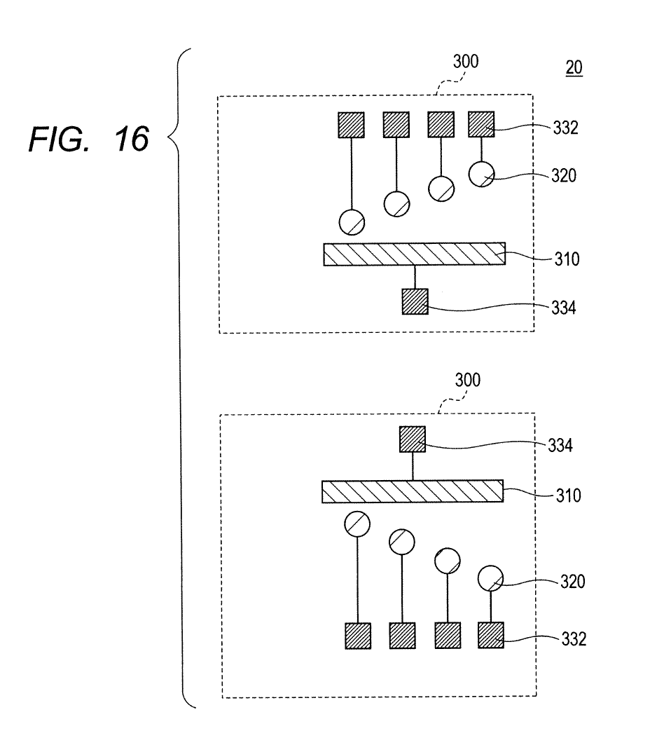

FIG. 16 is a plan view showing a configuration of TEG 300 used in a semiconductor device according to a ninth embodiment. The TEG 300 according to the present embodiment is the same as that of the second embodiment except that the TEG 300 has multiple pairs of the first contact 320 and the first electrode pad 332 for one first gate electrode 310.

Specifically, the first contacts 320 included in one TEG 300 are located on the same side with respect to the first gate electrode 310, and the distances between the first contacts 320 and the first gate electrode 310 are different from each other. The first contacts 320 included in one TEG 300 are respectively coupled to different first electrode pads 332.

Also in the present embodiment, the same effects as those of the second embodiment can be obtained. As described above, in the method described with reference to FIG. 4, the calculation accuracy varies depending on the distance between the first gate electrode 310 and the first contact 320. On the other hand, in the present embodiment, the process shown in FIG. 6 or FIG. 8 is performed on each first contact 320 in the TEGs 300. Therefore, it is possible to improve the calculation accuracy of the magnitude of the superposition error and the TDDB life.

### Tenth Embodiment

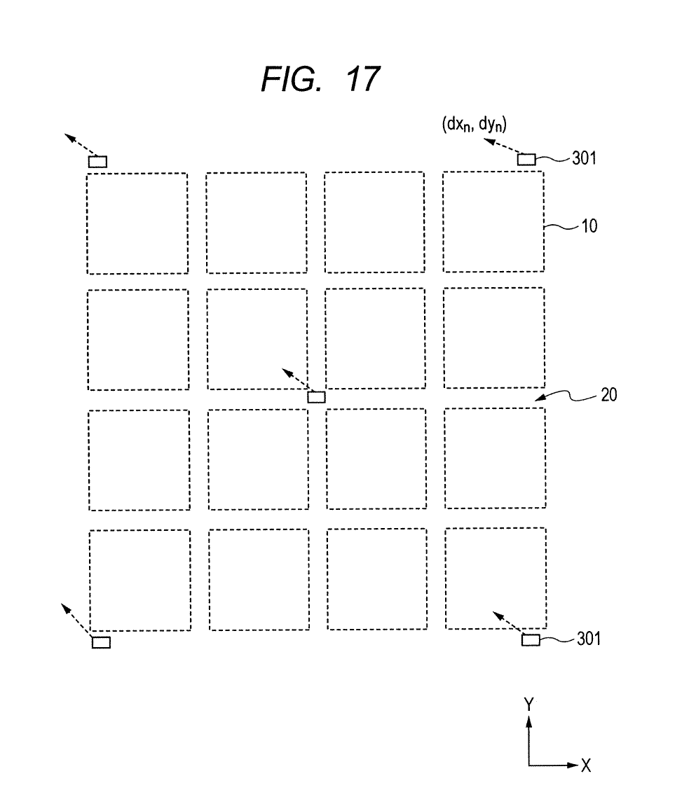

FIG. 17 is a plan view showing a configuration of a semiconductor device according to a tenth embodiment. In an example shown in the present embodiment, multiple chip areas 10 are coupled in matrix form. In other words, multiple chip areas 10 are formed in one substrate 100 (including a substrate in a wafer state). Three or more TEG groups 301 are provided in the substrate 100. For example, each TEG group 301 includes multiple TEGs 300 shown in FIG. 13, and as shown in FIG. 13, the superposition error (dx, dy) at the position of the TEG group 301 can be calculated. It is possible to calculate an in-plane distribution of superposition errors in the substrate 100 by applying the superposition errors (dx, dy) calculated at each point to the above formula (5).

Although the embodiments of the present invention have been described with reference to the drawings, these are examples of the present invention and a variety of configurations other than the above can be employed.

What is claimed is:

1. A method of manufacturing a semiconductor device, the method comprising:
preparing a semiconductor device including a first contact and a first gate electrode located adjacent to the first contact;
measuring a first leakage current generated between the first contact and the first gate electrode;
obtaining conversion data indicating a correlation between a distance between a contact coupled to an impurity layer that is a source or a drain of a transistor and a gate electrode of the transistor and a magnitude of a leakage current generated between the contact and the gate electrode; and
calculating a distance between the first contact and the first gate electrode by using the first leakage current and the conversion data.

2. The method of manufacturing a semiconductor device according to claim 1,
wherein the semiconductor device includes a transistor, and
wherein a TDDB life between the gate electrode and the contact included in the transistor is calculated by using the distance between the first contact and the first gate electrode after calculating the distance.

3. A method of manufacturing a semiconductor device, the method comprising:
preparing a semiconductor device including a TEG having a first contact, a first gate electrode located adjacent to the first contact, and a transistor;
measuring a first leakage current generated between the first contact and the first gate electrode;
obtaining conversion data indicating a correlation between a TDDB life between a contact coupled to an impurity layer that is a source or a drain of a transistor and a gate electrode of the transistor and a magnitude of a leakage current generated between the contact and the gate electrode; and
calculating the TDDB life between the contact and the gate electrode of the transistor by using the first leakage current and the conversion data.

4. The method of manufacturing a semiconductor device according to claim 2,
wherein the semiconductor device has the first gate electrode and the first contact as a TEG.

5. The method of manufacturing a semiconductor device according to claim 4,
wherein the semiconductor device has a semiconductor substrate and an insulating film partially formed over a surface of the semiconductor substrate, and
wherein the TEG is formed over the insulating film.

6. The method of manufacturing a semiconductor device according to claim 4,
wherein the semiconductor device has a plurality of the TEGs in each of which a distance between the first gate electrode and the first contact is different from that in the other TEGs, and
wherein the first leakage current is measured for each of the TEGs in the step of measuring the first leakage current.

7. The method of manufacturing a semiconductor device according to claim 4,
wherein the semiconductor device has a plurality of the TEGs in each of which an extending direction of the first gate electrode is different from that in the other TEGs, and
wherein the first leakage current is measured for each of the TEGs in the step of measuring the first leakage current.

8. The method of manufacturing a semiconductor device according to claim 4,
wherein the TEG has a plurality of the first contacts, distances between the first contacts and the first gate electrode being different from each other.

9. The method of manufacturing a semiconductor device according to claim 4,
wherein the TEG has a plurality of the first contacts, distances between the first contacts and the first gate electrode being the same, and
wherein the first contacts are coupled to the same electrode pad.

10. The method of manufacturing a semiconductor device according to claim 4,
wherein the TEG has a second gate electrode which extends in parallel with the first gate electrode and is located on the opposite side of the first gate electrode with respect to the first contact.

11. The method of manufacturing a semiconductor device according to claim 4,
wherein the TEG has two first contacts located on the opposite side of each other with respect to the first gate electrode.

12. The method of manufacturing a semiconductor device according to claim 1,
wherein a plurality of the semiconductor devices are formed in one substrate,
wherein the first gate electrode and the first contact are formed as a TEG in the substrate,
wherein the substrate has a plurality of the TEGs which are separated from each other with at least one semiconductor device in between,
wherein the first leakage current is measured for each of the TEGs in the step of measuring the first leakage current, and
wherein the distance is calculated for each of the TEGs in the step of calculating the distance, and further, a distribution of superposition errors between an exposure process for forming the first electrode and an exposure process for forming the first contact in the substrate is calculated by using positions of the TEGs and the distances.

13. The method of manufacturing a semiconductor device according to claim 1,
wherein there are a plurality of the conversion data according to a structure of the semiconductor device, and
wherein the conversion data according to the structure of the semiconductor device is obtained in the step of obtaining the conversion data.

14. A semiconductor device comprising:
a substrate;
an insulating film formed over a surface of the substrate; and
a TEG formed over the insulating film,
wherein the TEG includes
a first gate electrode located over the insulating film,
a first contact which is located over the insulating film and located adjacent to the first gate electrode,
a first electrode pad coupled to the first contact, and
a second electrode pad coupled to the first gate electrode.

15. The semiconductor device according to claim 14,
wherein the insulating film is an element separating film.

16. The semiconductor device according to claim 14,
wherein the first electrode pad is coupled to only the first contact via wiring, and
wherein the second electrode pad is coupled to only the first gate electrode via wiring.

17. The semiconductor device according to claim 14, further comprising:
a transistor including a circuit; and
a second contact coupled to an impurity layer that is a source or a drain of the transistor.

18. The semiconductor device according to claim 14, further comprising:
a plurality of the TEGs in each of which a distance between the first gate electrode and the first contact is different from that in the other TEGs.

19. The semiconductor device according to claim 14, further comprising:
a plurality of the TEGs in each of which an extending direction of the first gate electrode is different from that in the other TEGs.

20. The semiconductor device according to claim 14,
wherein the TEG has a plurality of the first contacts, distances between the first contacts and the first gate electrode being different from each other.

21. The semiconductor device according to claim 14,
wherein the TEG has a plurality of the first contacts, distances between the first contacts and the first gate electrode being the same, and
wherein the first contacts are coupled to the same electrode pad.

22. The semiconductor device according to claim 14,
wherein the TEG has a second gate electrode which extends in parallel with the first gate electrode and is located on the opposite side of the first gate electrode with respect to the first contact.

23. The semiconductor device according to claim 14,
wherein the TEG has two first contacts located on the opposite side of each other with respect to the first gate electrode.
